(19) United States
(12) Patent Application Publication
(10) Pub. No.: US 2007/0152316 A1
(43) Pub. Date: Jul. 5, 2007

(54) Interposer pattern with pad chain

(75) Inventors: Jung-su Ryu, Seongnam-si (KR); Byeong-yun Kim, Seoul (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/649,049

(22) Filed: Jan. 3, 2007

(30) Foreign Application Priority Data
Jan. 3, 2006 (KR) 10-2006-0000473

(51) Int. Cl. H01L 23/02

(52) U.S. Cl. 257/686

(57) ABSTRACT

Provided is an interposer pattern having a conductive material for forming a pad chain that can reduce a wafer test time. The interposer pattern includes one or more interposers and an external conductive material for the pad chain. Each of the interposers includes a plurality of pad pairs internally interconnected. The external conductive material is disposed at external sides of the interposers to interconnect the pad pairs of one of the interposers or to interconnect at least two of the interposers. The external conductive material can be disposed at scribe lanes of a wafer.

### CROSS-REFERENCE TO RELATED PATENT APPLICATION

This application claims the benefit of priority under 35 U.S.C. § 119 to Korean Patent Application No. 10-2006-0000473, filed on Jan. 3, 2006, in the Korean Intellectual Property Office, the disclosure of which is incorporated herein in its entirety by reference.

### BACKGROUND OF THE INVENTION

1. Field of the Invention

The present invention relates to systems and methods for testing a semiconductor wafer, and more particularly, to systems and methods for testing an interposer.

2. Description of the Related Art

A multi chip package (MCP) and a system in package (SIP) are fabricated by stacking a plurality of chips on a single package. The MCP and the SIP are very effective in space utilization of a printed circuit board (PCB) on which the package is mounted. The chips stacked on the package sometimes operate independently from each other and sometimes exchange signals between them. At this point, when pads to and from which the signals exchanged between the chips are inputted and outputted are properly arrayed, the pads can be directly interconnected through a bonding wire during the assembling process. However, the pads cannot be directly interconnected during the assembling process except for a case where the pads have been properly designed and arrayed considering the relationship between the chips to be stacked.

To solve this problem, an interposer is disposed between the stacked chips.

FIG. 1 illustrates an example of conventional interposers formed on a wafer.

Referring to FIG. 1, the conventional interposer corresponds to a single chip and includes a plurality of pad pairs interconnected by a conductive material, such as a metal line.

FIG. 2 is a top plan view of a conventional SIP having stacked chips electrically interconnected by an interposer. Referring to FIG. 2, a first chip Chip1, an interposer I/P, and a second chip Chip2 are stacked in a single package PKG. The interposer I/P is disposed between the first and second chips Chip1 and Chip 2.

When a first pad 1 of the second chip Chip 2 needs to be connected to a first pad 1′ of the first chip Chip1, pads A and A′ of the interposer I/P are used for the connection between the first pads 1 and 1′. That is, the first pad 1 of the second chip Chip 2 is connected to the pad A of the interposer I/P, and the first pad 1′ of the first chip Chip1 is connected to the pad A′ of the interposer I/P. The pads A and A′ of the interposer I/P are electrically interconnected with a metal line, as illustrated in FIG. 1. Consequently, the first pad 1 of the second chip Chip2 is electrically connected to the first pad 1′ of the first chip Chip1.

Likewise, a second pad 2 of the second chip Chip2 is connected to a second pad 2′ of the first chip Chip1 via pads B and B′ of the interposer I/P, and a third pad 3 of the second chip Chip2 is connected to a third pad 3′ of the first chip Chip1 via pads C and C′ of the interposer I/P.

FIG. 3 is a schematic sectional view of the conventional SIP of FIG. 2 having the stacked chips and the interposer that are interconnected by bonding wires. Referring to FIG. 3, the interposer I/P is disposed over the second chip Chip2, and the first chip Chip1 is disposed over the interposer I/P. The second chip Chip2, the interposer I/P and the first chip Chip1 are electrically interconnected by bonding wires, as shown.

In this case, it is most important to test whether there exists an electrical open of the metal lines interconnecting the pad pairs of the interposer. If an electrical open does exists, then the connections between the corresponding chips will fail. In general, the presences of an electrical open of the metal lines is tested using a probe card having as many probe tips as the pads of the interposer. That is, the probe card is brought into contact with each interposer to test the electrical open of the metal lines.

The interposers are designed considering the electrical characteristics of the chips that are electrically interconnected by the interposers. For example, the interposers are designed considering a current, a voltage, and a frequency of a signal that is to be transmitted through the interposers. However, since the interposer includes only the metal lines and the pads, it can be fabricated through a simple process. Therefore, when considering the current process technology, there is little possibility that a failure will occur in the fabrication process.

Nevertheless, separately testing the interposers of the single wafer in order to test for the presence of an electrical open of the metal lines is time-consuming and costly, leading to an increase in the manufacturing cost of the final product.

### SUMMARY OF THE INVENTION

The present invention provides an interposer pattern having a conductive material for forming a pad chain that can reduce the wafer test time.

According to an aspect of the present invention, there is provided an interposer assembly including: one or more interposers, each interposer including a plurality of pad pairs, each pad pair comprising a pair of internally interconnected pads; and an external conductive material disposed at external sides of the one or more interposers and configured to interconnect a set of pad pairs from at least one of the one or more interposers.

The external conductive material can be configured to serially interconnect the set of pad pairs from the at least one of the interposers.

The external conductive material can be configured to serially interconnect interposers from the one or more interposers in a horizontal direction or in a vertical direction.

The external conductive material can be formed from a material that is substantially identical to an internal conductive material used for internally interconnecting the pads.

The external conductive material can be configured to connect pad pairs from one interposer from the one or more interposers.

The external conductive material can be configured to connect pad pairs from a plurality of interposers from the one or more interposers.

The external conductive material can be configured to connect pad pairs from one interposer from the one or more interposers and to connect pad pairs from a plurality of interposers from the one or more interposers.

The interposer assembly can further comprise a wafer on which the one or more interposers is disposed.

In accordance with another aspect of the invention, provided is a wafer comprising: a plurality of interposers, each interposer including a plurality of pad pairs, each pad pair including at least two pads internally interconnected; and a pad chain pattern disposed at external sides of the interposers to interconnect at least two pad pairs of one or more of the plurality of interposers.

The pad chain pattern can be configured to serially interconnect the at least two pad pairs of the one or more of the plurality interposers.

The pad chain pattern can be configured to serially interconnect interposers from the plurality of interposers in a horizontal direction or in a vertical direction.

The pad chain pattern can be formed of a material that is substantially the same as an internal conductive material used for internally interconnecting the pads.

The pad chain pattern can be disposed at scribe lanes of the wafer.

The pad chain pattern can be configured to connect pad pairs from one interposer from the plurality of interposers.

The pad chain pattern can be configured to connect pad pairs from a plurality of interposers from the plurality of interposers.

The pad chain pattern can be configured to connect pad pairs from one interposer from the plurality of interposers and to connect pad pairs from a plurality of interposers from the plurality of interposers.

In accordance with another aspect of the invention, provided is a mask configured to manufacture a wafer comprising: a plurality of interposers, each interposer including a plurality of pad pairs, each pad pair including at least two pads internally interconnected; and a pad chain pattern disposed at external sides of the interposers to interconnect at least two pad pairs of one or more of the plurality of interposers.

In accordance with another aspect of the invention, provided is a method of testing interposer comprising: providing a plurality of interposers, each interposer including a plurality of pad pairs, each pad comprising a pair of internally interconnected pads; connecting a group of pad pairs from one or more interposers from the plurality of interposers using an external conductive material to form a pad chain; contacting a first probe to a first pad in a first pad pair in the group of pad pairs and contacting a corresponding second probe to a last pad in a last pad pair in the group of pad pairs; applying an electrical signal to at least one of the first and second probes to determine the presence of an electrical open in the group of pad pairs.

The method can further comprise connecting pad pairs from one interposer from the one or more interposers.

The method can further comprise connecting pad pairs from a plurality of interposers from the one or more interposers.

The method can further comprise connecting pad pairs from one interposer from the one or more interposers and connecting pad pairs from a plurality of interposers from the one or more interposers.

### BRIEF DESCRIPTION OF THE DRAWINGS

The above and other features and advantages of the present invention will become more apparent by describing in detail exemplary embodiments thereof with reference to the attached drawings, in which:

FIG. 1 illustrates an example of conventional interposers formed on a wafer;

FIG. 2 is a top plan view of a conventional SIP having stacked chips electrically interconnected by an interposer;

FIG. 3 is a schematic sectional view of the conventional SIP of FIG. 2 having the stacked chips and the interposer that are connected by bonding wires;

FIG. 4 is a conceptual view illustrating an embodiment of interposers with a conductive material for a pad chain and a test of the interposers according aspects of the present invention;

FIG. 5 is a view illustrating an embodiment of interposers with a conductive material for a pad chain according to aspects of the present invention; and

FIG. 6 is a view illustrating another embodiment of interposers with a conductive material for a pad chain according to aspects of the present invention.

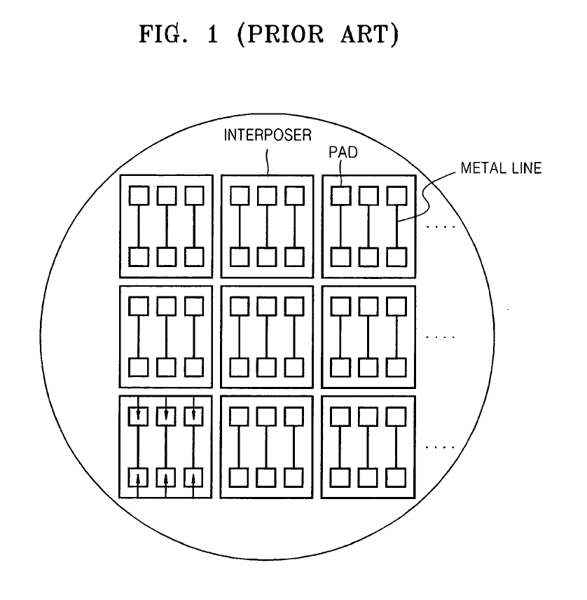

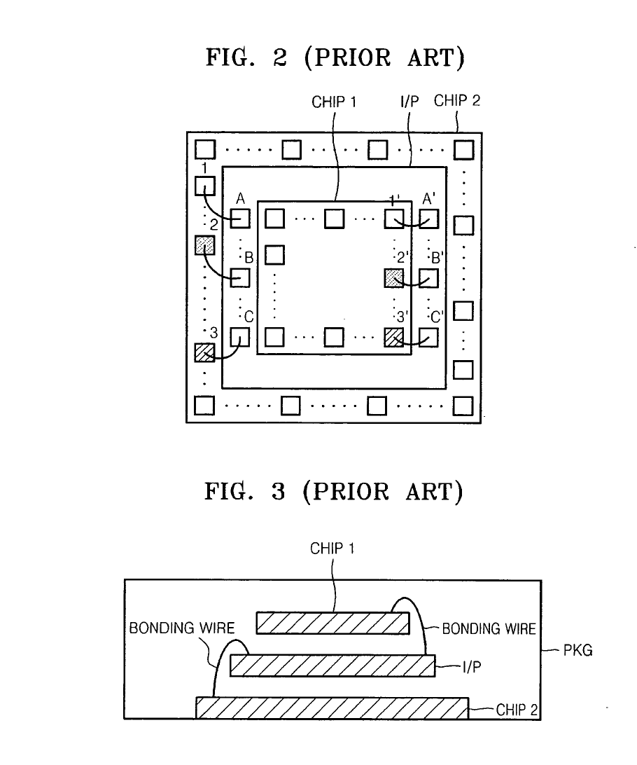

### DETAILED DESCRIPTION OF THE PREFERRED EMBODIMENTS

The attached drawings illustrate preferred embodiments demonstrating aspects of the present invention. Hereinafter, the embodiments will be described in detail with reference to the attached drawings. The invention, however, can be embodied in many different forms and should not be construed as limited to the embodiments set forth herein. Like reference numerals in the drawings denote like elements.

It will be understood that, although the terms first, second, etc. can be used herein to describe various elements, these elements should not be limited by these terms. These terms are used to distinguish one element from another. For example, a first element could be termed a second element, and, similarly, a second element could be termed a first element, without departing from the scope of the present invention. And, as used herein, the wording “and/or” includes each individual item listed and any combination of items.

It will also be understood that when an element is referred to as being “on” or “connected” or “coupled” to another element, it can be directly on or connected or coupled to the other element or intervening elements can be present. In contrast, when an element is referred to as being “directly on” or “directly connected” or “directly coupled” to another element, there are no intervening elements present. Other words used to describe the relationship between elements should be interpreted in a like fashion (e.g., “between” versus “directly between,” “adjacent” versus “directly adjacent,”etc.).

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements, and/or components, but do not preclude the presence or addition of one or more other features, steps, operations, elements, components, and/or groups thereof.

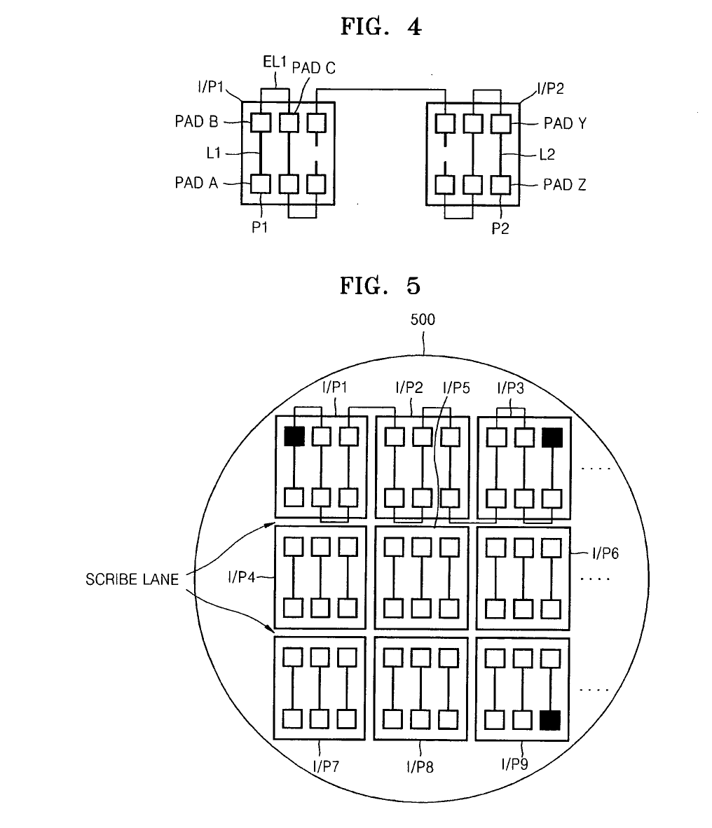

FIG. 4 is a conceptual view illustrating interposers with a conductive material for a pad chain and a test of the interposers according the present invention.

Referring to FIG. 4, each of two adjacent interposers, referred to as I/P1 and I/P2, includes a plurality of pairs of pads, and each pair of pads are internally interconnected by an internal line, such as a metal line. In FIG. 4 interposer I/P1 has 3 pairs of pads and interposer I/P2 has 3 pairs of pads. For example, for interposer I/P1, pads A and B form a pad pair connected by a metal line L1. Similarly, for interposer I/P2, pads C and D form a pad pair connected by metal line L2. However, the present invention is not limited to interposers having only 3 pairs of pads. In fact, there is no inherent limit on the number of pad pairs that could be included on an interposer.

The pad pairs of the adjacent interposers are externally interconnected in series by external lines to form a pad chain. As an example, in FIG. 4 pad B is connected to pad C via external line EL1. The internal lines and the external lines are generally formed of the same conductive material. However, in various embodiments, the internal lines and the external lines can be formed of different conductive materials.

The existence of an electrical open of the serially-interconnected pads (or “pad chain”) of the interposers can be tested when a pair of probes P1 and P2 are brought into contact with the first pad A of the first interposer I/P1 and the last pad Z of the second interposer I/P2. That is, since the pads of the interposers I/P1 and I/P2 are serially connected, an electrical open in the line between a pad pair can be detected.

The present invention proposes that manufactured interposers be externally and electrically interconnected to form a pad chain.

FIG. 5 is a view illustrating an embodiment of interposers with a conductive material for a pad chain according to aspects of the present invention.

Referring to FIG. 5, a plurality of interposers are formed on one wafer 500. For conciseness, only nine interposers I/P1 through I/P9 are illustrated in FIG. 5. When the first through third interposers I/P1 through I/P3 form a pad chain, the presence of an electrical open is tested using probes that are brought into contact with the first pad (shaded in black) of the first interposer IP1 and the last pad (shaded in black) of the third interposer IP3, as described with respect to FIG. 4.

When the first through ninth interposers IP1 through IP9 form a pad chain (not illustrated), their electrical open is tested using probes that are brought into contact with the first pad (shaded in black) of the first interposer IP1 and the last pad (shaded in black) of the ninth interposer IP9.

When no electrical open is detected during the test process, the test process is stopped and a subsequent process (i.e., a die sorting process) is performed. On the other hand, when an electrical open is detected during the test process, the conventional total inspection process is performed on the respective interposers.

In one embodiment. an external conductive material connected to the external sides of the interposers can be disposed at scribe lanes between interposer chips. The scribe lanes are cut with a diamond saw during the die sorting process. Accordingly, the external conductive material is removed by the die sorting process. Therefore, after completion of the die sorting process, no pads are interconnected by the external conductive material.

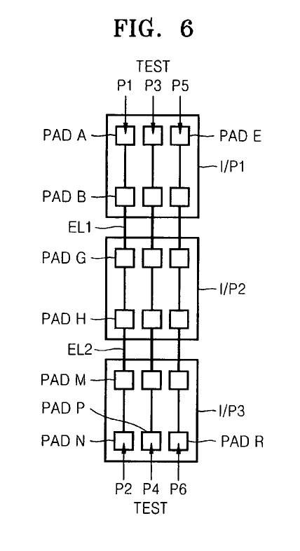

FIG. 6 is a view illustrating another embodiment of interposers with a conductive material for a pad chain according to aspects of the present invention.

Referring to FIG. 6, unlike the embodiment of FIG. 5, vertically-arranged interposers I/P1 through I/P3 are interconnected in series to form pad chains. Here, pads A and B form a pad pair in interposer I/P1, pads G and H form a pad pair in interposer I/P2, and pads M and N form a pad pair in interposer I/P3. A serial connection between pad A of interposer I/P1 and pad N of interposer I/P3 is formed by connecting pad B of interposer I/P1 to pad G of interposer I/P2 and by connecting pad H of interposer I/P2 to pad M of interposer I/P3. The presence of an electrical open can be tested by contacting a probe P1 to pad A of interposer I/P1 and a corresponding probe P2 to pad N of interposer I/P3.

The same arrangement exists for the other pad pairs of interposers I/P1 through I/P3. Thus, contacting a probe P3 to pad C of interposer I/P1 and a corresponding probe P4 to pad P of interposer I/P3 tests for the presence of an electrical open of the respective pad pairs. And contacting a probe P5 to pad E of interposer I/P1 and a corresponding probe P6 to pad R of interposer I/P3 tests for the presence of an electrical open of the respective pad pairs.

Although FIG. 6 illustrates that probes are brought into contact with six pads in order to test for the presence of an electrical open of the interposers, the present invention is not limited to this. That is, the presence of an electrical open of all the interposers of a wafer can be detected by one inspection process.

For example, the arrangement of FIG. 6 could be modified such that pads N and P of interposer I/P3 are connected with an external line (not shown) and pads C and E of interposer I/P1 are connected with an external line (not shown), while the connections between the pads of interposers I/P1 and I/P2 remain the same as in FIG. 6 and the connections between the pads of interposers I/P2 and I/P3 remain the same as in FIG. 6. In this embodiment, a serial connection between pad A of interposer I/P1 and pad R of interposer I/P3 is created. The presence of an electrical open can be tested by contacting a probe at pad A of interposer I/P1 and contacting a corresponding probe at pad R of interposer I/P3.

When the interposer patterns illustrated in FIGS. 5 and 6 are formed on a wafer, the wafer and a mask for manufacturing the wafer are also included in the scope of the present invention.

As described above, the present invention can reduce the test time for the wafer including an interposer pattern with the pad chain, thereby reducing the manufacturing cost of the final product.

While the present invention has been particularly shown and described with reference to exemplary embodiments thereof, it will be understood by those of ordinary skill in the art that various changes in form and details can be made therein without departing from the spirit and scope of the present invention as defined by the following claims. It is intended by the following claims to claim that which is literally described and all equivalents thereto, including all modifications and variations that fall within the scope of each claim.

What is claimed is:

1. An interposer assembly comprising:
one or more interposers, each interposer including a plurality of pad pairs, each pad pair comprising a pair of internally interconnected pads; and
an external conductive material disposed at external sides of the-one or more interposers and configured to interconnect a set of pad pairs from at least one of the one or more interposers.

2. The interposer assembly of claim 1, wherein the external conductive material is configured to serially interconnect the set of pad pairs from the at least one of the interposers.

3. The interposer assembly of claim 1, wherein the external conductive material is configured to serially interconnect interposers from the one or more interposers in a horizontal direction or in a vertical direction.

4. The interposer assembly of claim 1, wherein the external conductive material is formed from a material that is substantially identical to an internal conductive material used for internally interconnecting the pads.

5. The interposer assembly of claim 1, wherein the external conductive material is configured to connect pad pairs from one interposer from the one or more interposers.

6. The interposer assembly of claim 1, wherein the external conductive material is configured to connect pad pairs from a plurality of interposers from the one or more interposers.

7. The interposer assembly of claim 1, wherein the external conductive material is configured to connect pad pairs from one interposer from the one or more interposers and to connect pad pairs from a plurality of interposers from the one or more interposers.

8. The interposer assembly of claim 1, further comprising:
a wafer on which the one or more interposers is disposed.

9. A wafer comprising:
a plurality of interposers, each interposer including a plurality of pad pairs, each pad pair including at least two pads internally interconnected; and
a pad chain pattern disposed at external sides of the interposers to interconnect at least two pad pairs of one or more of the plurality of interposers.

10. The wafer of claim 9, wherein the pad chain pattern is configured to serially interconnect the at least two pad pairs of the one or more of the plurality interposers.

11. The wafer of claim 9, wherein the pad chain pattern is configured to serially interconnect interposers from the plurality of interposers in a horizontal direction or in a vertical direction.

12. The wafer of claim 9, wherein the pad chain pattern is formed of a material that is substantially the same as an internal conductive material used for internally interconnecting the pads.

13. The wafer of claim 9, wherein the pad chain pattern is disposed at scribe lanes of the wafer.

14. The wafer of claim 9, wherein the pad chain pattern is configured to connect pad pairs from one interposer from the plurality of interposers.

15. The wafer of claim 9, wherein the pad chain pattern is configured to connect pad pairs from a plurality of interposers from the plurality of interposers.

16. The wafer of claim 9, wherein the pad chain pattern is configured to connect pad pairs from one interposer from the plurality of interposers and to connect pad pairs from a plurality of interposers from the plurality of interposers.

17. A mask configured to manufacture a wafer comprising:
a plurality of interposers, each interposer including a plurality of pad pairs, each pad pair including at least two pads internally interconnected; and
a pad chain pattern disposed at external sides of the interposers to interconnect
at least two pad pairs of one or more of the plurality of interposers.

18. A method of testing interposer comprising:
providing a plurality of interposers, each interposer including a plurality of pad pairs, each pad comprising a pair of internally interconnected pads;
connecting a group of pad pairs from one or more interposers from the plurality of interposers using an external conductive material to form a pad chain;
contacting a first probe to a first pad in a first pad pair in the group of pad pairs and contacting a corresponding second probe to a last pad in a last pad pair in the group of pad pairs;
applying an electrical signal to at least one of the first and second probes to determine the presence of an electrical open in the group of pad pairs.

19. The method of claim 18, further comprising connecting pad pairs from one interposer from the one or more interposers.

20. The method of claim 18, further comprising connecting pad pairs from a plurality of interposers from the one or more interposers.

21. The method of claim 18, further comprising connecting pad pairs from one interposer from the one or more interposers and connecting pad pairs from a plurality of interposers from the one or more interposers.
